(19) United States
(12) Patent Application Publication
(10) Pub. No.: US 2026/0112589 A1
(43) Pub. Date: Apr. 23, 2026

(54) SEMICONDUCTOR SYMMETRIC PROCESS CHAMBER ARCHITECTURE

(71) Applicant: Applied Materials, Inc., Santa Clara, CA (US)

(72) Inventors: Yogananda SARODE VISHWANATH, Bangalore (IN); Steven E. BABAYAN, Los Altos, CA (US)

(21) Appl. No.: 18/923,107

(22) Filed: Oct. 22, 2024

(51) Int. Cl. H01J 37/32

(52) U.S. Cl. CPC H01J 37/32899; H01J 37/32834; H01J 2237/334

(57) ABSTRACT

A module for semiconductor processing is disclosed herein. The module includes a first chamber, a second chamber, and an exhaust assembly. The first chamber includes a first chamber body having the first central axis, a first substrate support assembly disposed coincident with the first central axis, and a plurality of first exhaust ports disposed through the first chamber body. The second chamber includes a second chamber body having the second central axis coincident with the first central axis, a second substrate support assembly coincident with the second central axis, and a plurality of second exhaust ports disposed through the second chamber body. The exhaust assembly includes a port coupled to the plenum, the plenum concentric with the first central axis and the second central axis, and a plurality of exhaust conduits fluidly coupling the plurality of first exhaust ports, the plurality of second exhaust ports, and the plenum.

### BACKGROUND

### Field

Embodiments of the present subject matter generally relates to etch modules. More particularly, the subject matter relates to stacked etch chambers to improve throughput for semiconductor systems.

### Description of the Related Art

Electronic devices, such as flat panel displays and integrated circuits, commonly are fabricated by a series of process steps in which layers are deposited on a substrate and the deposited material is etched into desired patterns. The process steps commonly include physical vapor deposition (PVD), chemical vapor deposition (CVD), plasma enhanced CVD (PECVD), and other plasma processing. Specifically, a plasma process requires supplying a process gas mixture to a vacuum chamber, and applying electrical or electromagnetic power (RF power) to excite the process gas into a plasma state. The plasma decomposes the gas mixture into ion species that perform the desired deposition or etch processes.

One problem encountered with plasma processes is the difficulty associated with maintaining uniform plasma density over the substrate surface during processing while increasing throughput. One reason for the difficulty in increasing throughput is due to facility space required to create modules with systematic flow.

Therefore, a need exists for a plasma processing module that improves throughput, has a reduced foot print in a facility, and maintains plasma uniformity control.

### SUMMARY

Embodiments of the present disclosure generally relate to semiconductor processing modules with stacked chambers. In one embodiment, a module for semiconductor processing is disclosed herein. The module includes a first chamber, a second chamber, and an exhaust assembly. The first chamber includes a first chamber body having the first central axis, a first substrate support assembly disposed coincident with the first central axis, and a plurality of first exhaust ports disposed through the first chamber body. The second chamber includes a second chamber body having the second central axis coincident with the first central axis, a second substrate support assembly coincident with the second central axis, and a plurality of second exhaust ports disposed through the second chamber body. The exhaust assembly includes a port coupled to the plenum, the plenum concentric with the first central axis and the second central axis, and a plurality of exhaust conduits fluidly coupling the plurality of first exhaust ports, the plurality of second exhaust ports, and the plenum.

In another embodiment, a module for semiconductor processing is disclosed herein. The module for semiconductor processing includes a first etch chamber, a second etch chamber, and an exhaust assembly. The first etch chamber includes a first chamber body having the first axis and a plurality of first exhaust ports fluidly coupled to the first chamber body. The second etch chamber is symmetric to the first etch chamber and includes a second chamber body having the second axis coincident with the first axis and a plurality of second exhaust ports fluidly coupled to the second chamber body and is disposed symmetrically with the plurality of first exhaust ports. The exhaust assembly includes a plenum coupled to the second etch chamber, disposed opposite the first etch chamber, and coincident with the first axis and the second axis and a plurality of exhaust conduits fluidly coupling the plurality of first exhaust ports, the plurality of second exhaust ports, and the plenum.

In another embodiment, a system for semiconductor processing is disclosed herein. The system for semiconductor processing includes a factory interface, a stacked process module, a first load-lock chamber, and a second load-lock chamber. The factory interface includes a base surface and a robot disposed on the base surface and within the transfer volume of the factory interface. The stacked process module includes a first chamber, a second chamber coupled to the second chamber, and an exhaust assembly coupled to both of the first chamber and the second chamber. The exhaust assembly includes a plenum coupled to the second chamber and disposed opposite the first chamber and a plurality of exhaust conduits fluidly coupling the first chamber and the second chamber to the plenum. The first load-lock chamber is disposed between the first chamber and the factory interface. The first load-lock chamber includes a substrate shuttle configured to translate between the first load-lock chamber and the first chamber of the stacked process module. The second load-lock chamber is disposed between the second chamber and the factory interface the second load-lock chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, as the disclosure may admit to other equally effective embodiments.

FIG. 1A is a schematic, view of a processing module according to one or more embodiments.

FIG. 1B is a schematic, cross-sectional view of a plasma processing apparatus according to one or more embodiments.

FIG. 2 is a schematic depiction of the layout of exhaust conduits extending through the processing apparatus of FIG. 1B according to one or more embodiments.

FIG. 3 is a schematic depiction of the layout of a substrate processing system with the processing module of FIG. 1A incorporated therein according to one or more embodiments.

FIG. 4 is a schematic depiction of the layout of a substrate processing system with the processing module of FIG. 1A incorporated therein according to one or more embodiments.

FIG. 5 is a schematic side view of a substrate processing system with the processing module of FIG. 1A incorporated therein according to one or more embodiments.

FIG. 6 is a schematic side view of a substrate processing system with the processing module of FIG. 1A incorporated therein according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

As previously mentioned, a problem in conventional plasma systems is the difficulty in providing uniform plasma density due to asymmetry in the chamber. In addition to the difficulty in providing uniform plasma density, floor space within a manufacturing space is always a valuable commodity. Embodiments of the present invention mitigate these problems by providing a module design that allows for stacked chambers with extremely symmetrical electrical, thermal, and gas flow conductance through each chamber and a symmetric shared exhaust assembly. By providing such symmetry, plasma formed within the chamber naturally has improved uniformity across the surface of a substrate disposed in a processing region of the chamber. Further, other chamber additions, such as providing the ability to manipulate the gap between upper and lower electrodes as well as between a gas inlet and a substrate being processed, provides a large process window that enables better control of plasma processing and uniformity as compared to conventional systems.

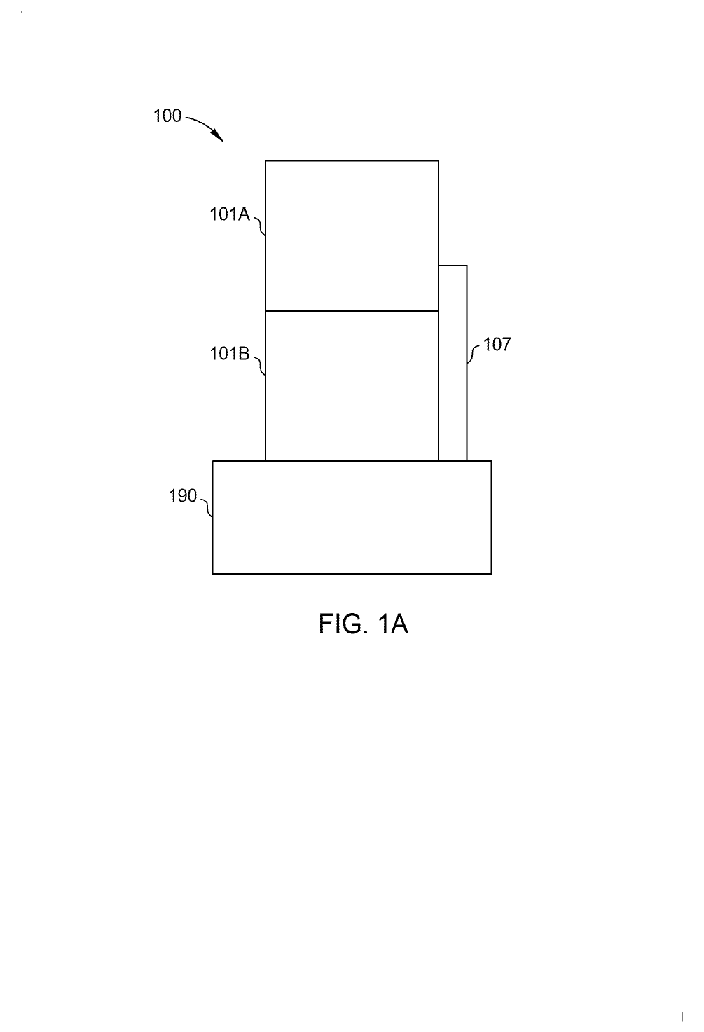

FIG. 1A is a schematic, view of a processing module 100 according to one or more embodiments. The module 100 for semiconductor processing has a first chamber 101A, a second chamber 101B, an exhaust assembly 190, and an exhaust conduit 107. While only one exhaust conduit 107 is illustrated, the processing module 100 includes a plurality of symmetrically distributed exhaust conduits 107, e.g., three exhaust conduits may be distributed symmetrically about the first and second chambers 101A, 101B.

FIG. 1B is a schematic, cross-sectional view of the processing module 100 according to one embodiment of the present disclosure. The plasma processing module 100 includes the first chamber 101A, the second chamber 101B, a support structure 130, and the exhaust assembly 190. The first chamber 101A and the second chamber 101B are configured to provide enhanced operation through similar and symmetric arrangement. For example, the first chamber 101A and second chamber 101B are both plasma etch chambers, plasma enhanced chemical vapor deposition (PECVD) chambers, physical vapor deposition (PVD) chambers, plasma treatment chambers, ion implantation chambers, atomic layer etching chambers, atomic layer deposition chambers, or other suitable vacuum processing chambers. As shown in FIG. 1B, each of the first chamber 101A and the second chamber 101B generally includes a chamber lid assembly 110, a chamber body assembly 140. Each chamber and lid assembly 110 collectively encloses a processing region 102. The processing regions 102 are both coupled to an evacuation region or plenum 104 of the exhaust assembly 190 of the processing module 100. In practice, processing gases are introduced into the processing region 102 and ignited into a plasma using radio frequency (RF) power. A substrate 105 is positioned on a substrate support assembly 160 and exposed to the plasma generated in the processing region 102 to perform a plasma process on the substrate 105, such as etching, PECVD, PVD, implantation, plasma annealing, plasma treating, abatement, or other plasma processes. Vacuum is maintained in the processing region 102 by the exhaust assembly 190, which removes spent processing gases and byproducts from the plasma process through the plenum 104.

The lid assembly 110 generally includes an upper electrode 112 isolated from and supported by the chamber body assembly 140 and a chamber lid 114 enclosing the upper electrode 112.

The upper electrode 112 is coupled to an RF power source 103 via a conductive gas inlet tube 126. The conductive gas inlet tube 126 is coaxial with a central axis (CA) of the chamber body assembly 140 so that both RF power and processing gases are symmetrically provided. The upper electrode 112 includes a showerhead plate 116 attached to a heat transfer plate 118. The showerhead plate 116, the heat transfer plate 118, and the gas inlet tube 126 are all fabricated from an RF conductive material, such as aluminum or stainless steel.

The showerhead plate 116 has a central manifold 120 and one or more outer manifolds 122. The one or more outer manifolds 122 circumscribe the central manifold 120. The central manifold 120 receives processing gases from a gas source 106 through the gas inlet tube 126 and distributes the received processing gases into a central portion of the processing region 102 through a plurality of gas passages 121. The outer manifold(s) 122 receives processing gases, which may be the same or a different mixture of gases received in the central manifold 120, from the gas source 106. The outer manifold(s) 122 then distributes the received processing gases into an outer portion of the processing region 102 through a plurality of gas passages 123. The manifolds 120, 122 have sufficient volume to function as a plenum so that uniform pressure is provided to each gas passage 121 associated with a respective manifold 120, 122. The dual manifold configuration of the showerhead plate 116 allows improved control of the delivery of gases into the processing region 102. For instance, processing gases provided to the central portion of the processing region 102, and thus the central portion of the substrate 105 positioned therein, may be introduced at a different flow rate and/or pressure than the processing gases provided to the outer portion of the processing region 102, and thus outer portion of the substrate 105. The multi-manifold showerhead plate 116 enables enhanced center to edge control of processing results as opposed to conventional single manifold versions.

The first chamber 101A and the second chamber 101B are supported by a support structure 130. The first chamber 101A and the second chamber 101B are coupled to the support structure 130. The first chamber 101A is disposed on a first support 131A of the support structure 130. The second chamber 101B is disposed on a second support 131B of the support structure 130. In some embodiments, the support structure 130 is disposed between the first chamber 101A, the second chamber 101B, and the exhaust assembly 190.

In some embodiments the first support 131A includes a shield 133 between the chamber body 142 of the first chamber 101A and a plasma source of the second chamber 101B.

Referring to FIGS. 1B, it can be seen that a processing gas from the gas source 106 is delivered into a ring manifold 128 concentrically disposed around the inlet tube 126. From the ring manifold 128, the processing gas is delivered through a plurality of gas tubes 129 to the outer manifold(s) 122. In one embodiment, the ring manifold 128 includes a recursive gas path to assure that gas flows equally from the ring manifold 128 into the gas tubes 129. The ring manifold 128 and the gas tubes 129 are fabricated from a conductive material, such as aluminum or stainless steel. Thus, the ring manifold 128 and the gas tubes 129 may influence the symmetry of the RF current, causing skewing of the electric field provided by the upper electrode 112, potentially resulting in an effect in the plasma uniformity within the process region 102.

To prevent such skewing in the electric field, the gas tubes 129 are positioned symmetrically about the central axis (CA) extending vertically through the processing chambers 101A, 101B. Thus, the gas tubes 129 extend from the centrally located ring manifold 128 at equidistant angles to deliver the processing gas through the cooling plate 118 and into the outer manifold(s) 122.

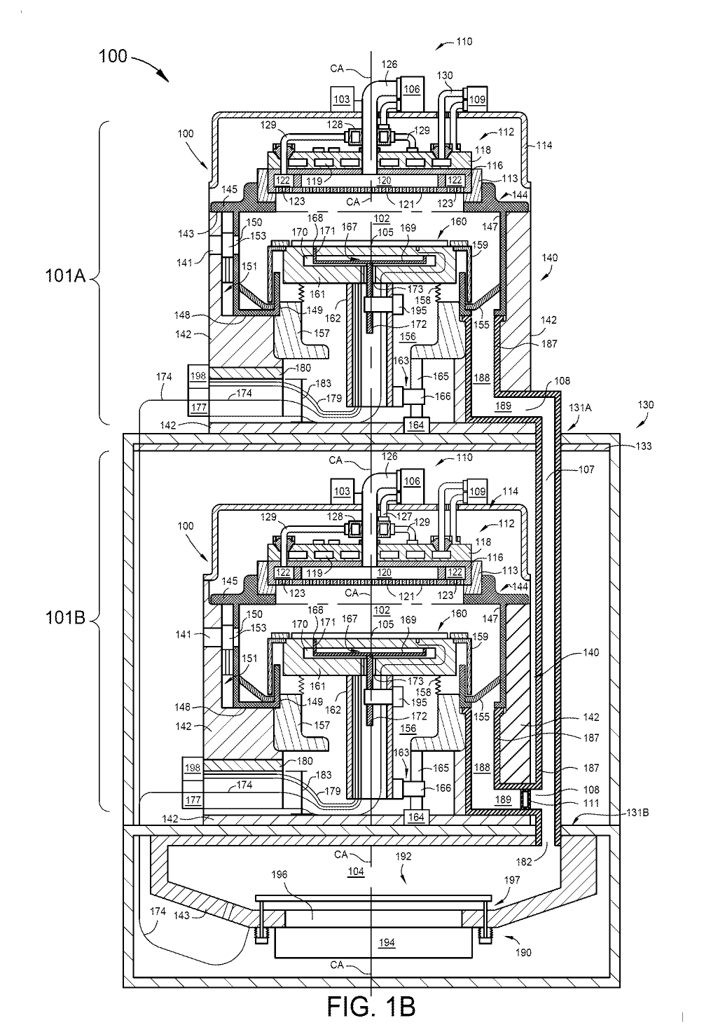

Referring to FIG. 1B and 2, the embodiment shown depicts three evacuation channels 188 coupled to three corresponding exhaust ports 108 of a plurality of exhaust ports 108. Each exhaust port 108 of the plurality of exhaust ports 108 is fluidly coupled to a corresponding exhaust conduit 107. The plurality of exhaust conduits 107 are symmetrically spaced apart. For example, each of the exhaust conduits 107 are spaced about 120° apart when there are three exhaust conduits 107. In some embodiments, the exhaust conduits 107 are about parallel to the central axis (CA). In other examples (not shown), more or fewer gas tubes 129 may be used as long as they are positioned symmetrically about the central axis (CA), i.e., at equidistant angles from one another. By employing a ring-shaped manifold and arranging the gas tubes 129 symmetrically about the central axis (CA), the electrical symmetry of the upper electrode 112 is significantly improved over conventional systems resulting in more uniform and consistent plasma formation in the processing region 102. Additionally, the symmetric arrangement of the gas tubes 129 provides gas in a uniformly polar array into the outer manifold 122, thereby providing azimuthal uniform pressure distribution within the outer manifold 122 and consequently, an azimuthally uniform flow of gas through the gas passages 123 into the processing region 102, thereby enhancing processing uniformity.

Referring to FIG. 1B, a heat transfer fluid is delivered from a fluid source 109 to the heat transfer plate 118. The fluid is circulated through one or more fluid channels 119 disposed in the heat transfer plate 118 and returned to the fluid source 109.

The chamber body assembly 140 includes a chamber body 142 fabricated from a conductive material resistant to processing environments, such as aluminum or stainless steel. The substrate support assembly 160 is centrally disposed within the chamber body 142 and positioned to support the substrate 105 in the processing region 102 symmetrically about the central axis (CA). The substrate support assembly 160 is disposed coincident with the central axis (CA). For example, a first substrate support assembly 160 of the first chamber 101A is disposed coincident with the first central axis (CA) of the first chamber 101A and a second substrate support assembly 160 of the second chamber 101B is disposed coincident with the second central axis (CA) of the second chamber 101B.

An upper liner assembly 144 that is disposed within an upper portion of the chamber body 142 circumscribing the processing region 102. The upper liner assembly 144 may be constructed from a conductive, process compatible material, such as aluminum, stainless steel, and/or yttria (e.g., yttria coated aluminum). In practice, the upper liner assembly 144 shields the upper portion of the chamber body 142 from the plasma in the processing region 102 and is removable to allow periodic cleaning and maintenance. In one embodiment, the upper liner assembly 144 is temperature controlled, such as by an AC heater (not shown) in order to enhance the thermal symmetry within the chamber and symmetry of the plasma provided in the processing region 102.

Referring to FIG. 1B, the chamber body 142 supports a flange 145 of the upper liner assembly 144. The flange 145 of the upper liner assembly 144 supports the upper electrode 112. An insulator 113 is positioned between the upper liner assembly 144 and the upper electrode 112 to provide electrical insulation between the chamber body assembly 140 and the upper electrode 112.

The upper liner assembly 144 includes an outer wall 147 attached to the flange 145, a bottom wall 148, and an inner wall 149. The outer wall 147 and inner wall 149 are substantially vertical, cylindrical walls. The outer wall 147 is positioned to shield the chamber body 142 from plasma in the processing region 102, and the inner wall 149 is positioned to at least partially shield the side of the substrate support assembly 160 from plasma in the processing region 102. The bottom wall 148 joins the inner and outer walls (149, 147) except in certain regions where evacuation passages 189 are formed, which are subsequently discussed herein.

The evacuation passages 189 are formed through the chamber body 142. The evacuation passages 189 are coupled to the plurality of exhaust ports 108 and are directed away from the central axis CA. In some embodiments, each exhaust port 108 of the plurality of exhaust ports 108 of the second chamber 101B each include a restrictor 111. The restrictor 111 is configured to equalize pressure. The restrictor 111 enhances uniformity of flow into the corresponding exhaust conduit 107 so that the flow from the processing region 102 of the first chamber 101A and flow from the processing region 102 of the second chamber 101B into the corresponding exhaust conduit 107 is about equal. In some embodiments, each exhaust conduit 107 of the plurality of exhaust conduits 107 corresponds to a first exhaust port 108 of the plurality of first exhaust ports of the first chamber 101A and a second exhaust port of the plurality of second exhaust ports of the second chamber 101B. The exhaust ports 108 are perpendicular to the central axis CA.

The processing region 102 is accessed through a slit valve tunnel 141 disposed in the chamber body 142 that allows entry and removal of the substrate 105 into/from the substrate support assembly 160. The upper liner assembly 144 has a slot 150 disposed therethrough that matches the slit valve tunnel 141 to allow passage of the substrate 105 therethrough. The chamber body assembly 140 includes a slit valve door assembly 151 that includes an actuator positioned and configured to vertically extend a slit valve door to seal the slit valve tunnel 141 and slot 150 and to vertically retract the slit valve door 153 to allow access through the slit valve tunnel 141 and slot 150. The slit valve door 153 may be constructed of a material substantially matching that of the upper liner assembly 144 (e.g., yttria coated aluminum) in order to provide increased electrical symmetry in the liner.

The substrate support assembly 160 is disposed centrally within a central region 156 of the chamber body assembly 140 and sharing the central axis (CA). That is, the central axis (CA) passes vertically through the center of the substrate support assembly 160. The substrate support assembly 160 is disposed coincident with the central axis (CA). The substrate support assembly 160 generally includes lower electrode 161 (or cathode) and a hollow pedestal 162, the center of which the central axis (CA) passes through, and is supported by a central support member 157 disposed in the central region 156 and supported by the chamber body 142. The central axis (CA) also passes through the center of the central support member 157. The RF power source 103 can be a plasma source. When RF power is supplied to the upper electrode 112 and the lower electrode 161, an electrical field formed therebetween ignites the processing gases present in the processing region 102 into a plasma. In some embodiments, the first chamber 101A has a first axis and second chamber 101B has a second axis coincident with the first axis of the first chamber 101A.

The lower electrode 161 is sealed to the central support member 157, such as by a bellows 158. Thus, the central region 156 is sealed from the processing region 102 and may be maintained at atmospheric pressure, while the processing region 102 is maintained at vacuum conditions.

An actuation assembly 163 is positioned within the central region 156 and attached to the chamber body 142 and/or the central support member 157. The actuation assembly 163 includes an actuator 164 (e.g., motor), a lead screw 165, and a nut 166 attached to the pedestal 162. In practice, the actuator 164 rotates the lead screw 165, which, in turn raises or lowers the nut 166, and thus the pedestal 162. Since the lower electrode 161 is supported by the pedestal 162, the actuation assembly 163 provides vertical movement of the lower electrode 161 relative to the chamber body 142, the central support member 157, and the upper electrode 112. Such vertical movement of the lower electrode 161 within the processing region 102 provides a variable gap between the lower electrode 161 and the upper electrode 112, which allows increased control of the electric field formed therebetween, in turn, providing greater control of the density in the plasma formed in the processing region 102. In addition, since the substrate 105 is supported by the lower electrode 161, the gap between the substrate 105 and the showerhead plate 116 may also be varied, resulting in greater control of the process gas distribution across the substrate 105.

A plasma screen 159 is also provided, supported by the lower electrode 161 and overlapping the inner wall 149 of the upper liner assembly 144, to protect the substrate support assembly 160 and the bellows 158 from the plasma in the processing region 102. Since the plasma screen 159 is coupled to and moves vertically with the pedestal 162, the overlap between plasma screen 159 the inner wall 149 of the upper liner assembly 144 is sufficient to allow the pedestal 162 to enjoy a full range of motion without the plasma screen 159 and the upper liner assembly 144 becoming disengaged and allowing exposure of the region below the pedestal 162 to become exposed to process gases.

The substrate support assembly 160 further includes a lift pin assembly 167 to facilitate loading and unloading of the substrate 105. The lift pin assembly 167 includes lift pins 168 attached to a lift pin plate 169. The lift pin plate 169 is disposed within an opening 170 within the lower electrode 161, and the lift pins 168 extend through lift pin holes 171 disposed between the opening 170 and the processing region 102. The lift pin plate 169 is coupled to a lead screw 172 extending through an aperture 173 in the lower electrode 161 and into the hollow pedestal 162. An actuator 195 (e.g., motor) may be positioned on the pedestal 162. Note, the actuator 195 is shown without hatching to minimize drawing clutter. The actuator 195 rotates a nut, which advances or retracts the lead screw 172. The lead screw 172 is coupled to the lift pin plate 169. Thus, as the actuator 195 causes the lead screw 172 to raise or lower the lift pin plate 169, the lift pins 168 to extend or retract. Therefore, the actuator 195 allows the lift pins 168 to be extended or retracted regardless of the vertical positioning of the lower electrode 161. By providing such separate actuation of the lift pins 168, the vertical positioning of the substrate 105 can be altered separately from the vertical positioning of the lower electrode 161 allowing greater control of positioning during both loading and unloading of the substrate 105 as well as during processing of the substrate 105, for example, by lifting the substrate during processing to allow backside gas to escape from under the substrate.

The substrate support assembly 160 further includes gas supply and vent lines 174 coupling the opening 170 with the plenum 104. The gas supply and vent lines 174 are routed centrally through the hollow pedestal 162 and out of the chamber body 142 through one of a plurality of access tubes 180 arranged in a spoke pattern symmetrical about the central axis (CA) as subsequently described. The gas supply and vent lines 174 provides for evacuation of the opening 170 in order to remove any processing gases that may leak into the opening 170 via the lift pin holes 171. In addition, evacuation of the opening 170 also aids in removing any processing gases that may be present on the backside of the substrate 105 disposed on the lower electrode 161 or lift pins 168.

The substrate support assembly 160 may also include a gas port disposed therethrough and coupled to an inert gas supply 177 via a gas supply line. The substrate support assembly 160 may further include one or more facility lines 179 routed from a facility manifold 198 to through one or more heat exchange channels (not shown) in the lower electrode 161 in order to provide temperature control to the lower electrode 161 during processing. The facility manifold 198 can supply fluids and RF power to the lower electrode 161. The facility lines 179 are routed from the lower electrode 161 through the hollow pedestal 162 and out of the chamber body 142 through one of the plurality of access tubes 180. The lower electrode 161 is coupled to an RF power source within the facility manifold 198 and routed through the hollow pedestal 162 via the facility lines 179.

In one embodiment, the lower electrode 161 is an electrostatic chuck, and thus includes one or more electrodes (not shown) disposed therein. A voltage source (not shown) biases the one or more electrodes with respect to the substrate 105 to create an attraction force to hold the substrate 105 in position during processing. Cabling coupling the one or more electrodes to the voltage source is routed through the hollow pedestal 162 and out of the chamber body 142 through one of the plurality of access tubes 180.

FIG. 2 is a schematic depiction of the layout of the access tubes 180 within spokes 191 of the chamber body assembly 140. Referring to FIGS. 1B and 2, the spokes 191 and access tubes 180 are symmetrically arranged about the central axis (CA) of the processing chambers 101A, 101B in a spoke pattern as shown. In the embodiment shown, three identical access tubes 180 are disposed through the chamber body 142 into the central region 156 to facilitate supply of a plurality of tubing and cabling from outside of the chamber body 142 to the lower electrode 161. In order to facilitate vertical movement of the lower electrode 161, the opening 183 through each of the access tubes 180 is approximately equal to the vertical travel of the lower electrode 161. For example, in one configuration, the lower electrode 161 is vertically movable a distance of approximately 7.2 inches. In this case, the height of the opening 183 in each of the access tubes 180 is also approximately 7.2 inches. Keeping these distances approximately the same helps minimize the length of the cabling required as well as preventing binding and wear of the cabling during vertical movement of the lower electrode 161. In addition, the width (W) of the spokes 191 is minimized such that a high aspect ratio (height:width) is provided, such that the open area for evacuation passages 189 is enhanced, while still allowing sufficient room for utilities (e.g., gas, wiring). Such a configuration reduces flow resistance of exhaust gases, resulting in reduced energy consumption due to pumping and smaller less costly pumps.

In order to further facilitate cable routing to the lower electrode 161, the cable routing is divided between the plurality of access tubes 180. For example, the fluid lines 179 and the gas supply and vent lines 174 may all be provided through the access tube 180a; cables for other electrical cables (e.g., to actuators 164, 195) may be provided through the access tube 180b; and the RF voltage feed and other electrical cable(s) (e.g., to electrodes for chucking function) may be provided through the access tube 180c. Thus, number and volume of cabling from outside of the chamber body 142 to the lower electrode 161 are divided between the access tubes 180 in order to minimize the size of the access tubes 180 while providing adequate clearance to facilitate the movement of the lower electrode 161.

The access tubes 180 may be constructed of materials such as aluminum or stainless steel. The symmetrical spoke arrangement of the access tubes 180 is designed to further facilitate electrical and thermal symmetry of the processing chambers 101A, 101B. In one embodiment, the access tubes 180 are positioned 120 degrees apart, and each of the access tubes 180 is aligned with a respective gas tube 129. The symmetrical arrangement of the access tubes 180 further provides electrical and thermal symmetry in the chamber body 142, and particularly in the processing region 102, in order to allow greater more uniform plasma formation in the processing region 102 and improved control of the plasma density over the surface of the substrate 105 during processing.

Still referring to FIGS. 1B and 2, the evacuation passages 189 are positioned in the upper liner assembly 144 symmetrically about the central axis (CA). The evacuation passages 189 allow evacuation of gases from the processing region 102 out of the chamber body 142 through a pump port 196. The pump port 196 is disposed centered about the central axis (CA) of the chamber body assembly 140 such that the gases are evenly drawn through the evacuation passages 189. In some embodiments, the plenum 104 includes the pump port 196 disposed coincident with the central axis (CA) of the processing module 100. Evacuation liners 187 may be respectively positioned below each of the evacuation passages 189 in evacuation channels 188 provided in the chamber body 142 in order to protect the chamber body 142 from processing gases during evacuation. The evacuation liners 187 may be constructed of materials similar to that of the upper liner assembly 144 as described above.

The evacuation channels 188 are positioned away from the processing region 102 such that substantially no electrical interaction exists. The symmetrical positioning of the evacuation channels 188 about the central axis (CA), however, provides improved thermal and gas flow symmetry within the processing chambers 101A, 101B. For instance, the symmetrical positioning of the evacuation channels 188 about the central axis (CA), and thus the processing region 102, promotes symmetrical removal of gases from the processing region 102, resulting in symmetrical flow of gases across the substrate 105. In addition, the symmetrical positioning of the evacuation channels 188, and the evacuation liners 187, promotes symmetry in the thermal distribution in the chamber. Thus, the symmetrical positioning of the evacuation channels 188 in the processing chambers 101A, 101B facilitates uniform plasma formation in the processing region 102 and allows greater control of the plasma density and gas flow in the processing region 102.

The exhaust assembly 190 is disposed opposite the second chamber 101B from the first chamber 101A. The exhaust assembly 190 includes a body 143, a plurality of conduit ports 182, the plenum 104, and a throttle valve 192 coupled to a vacuum pump 194. The body 143 coupled to the second support 131B of the support structure 130. The body 143 defines the plenum 104.

The plurality of conduit ports 182 are coupled to a corresponding exhaust conduit 107 of the plurality of exhaust conduits 107. The plenum 104 extends radially outward of the first chamber 101A and the second chamber 101B so that the plurality of conduit ports 182 are disposed radially outward of the first chamber body 142 and the second chamber body 142. The throttle valve 192 may be a poppet style valve used in conjunction with the vacuum pump 194 to control the vacuum conditions within the processing regions 102 by symmetrically drawing exhaust gases from the processing region 102 of the first chamber 101A and the processing region 102 of the second chamber 101B through the evacuation passages 189 and out of the exhaust conduits 107, further providing greater control of the plasma conditions in the processing region 102. A poppet style valve, as shown in FIG. 1B, provides a uniform, 360 degree gap 197 through which evacuation gases are drawn through the pump port 196. The pump port 196 is coincident with the central axis (CA).

Referring back to FIG. 1B, a mesh liner 155 is positioned in a lower portion of the upper liner assembly 144. The mesh liner 155 may be constructed from a conductive, process compatible material, such as aluminum, stainless steel, and/or yttria (e.g., yttria coated aluminum).

Thus, the annularly symmetric configuration of the mesh liner 155 provides a symmetric RF return to ground and bypasses any geometric asymmetries in the lower portion of the mesh liner 155.

Therefore, embodiments of the present disclosure solve the problem of conventional plasma systems with the difficulty in providing uniform plasma density due to asymmetry in the chamber by providing a chamber design that allows extremely symmetrical electrical, thermal, and gas flow conductance through the chamber. By providing such symmetry, plasma formed within the chamber naturally has improved uniformity across the surface of a substrate disposed in a processing region of the chamber. This improved symmetry, as well as other chamber additions, such as providing the ability to manipulate the gap between upper and lower electrodes as well as between a gas inlet and a substrate being processed, allows better control of plasma processing and uniformity as compared to conventional systems.

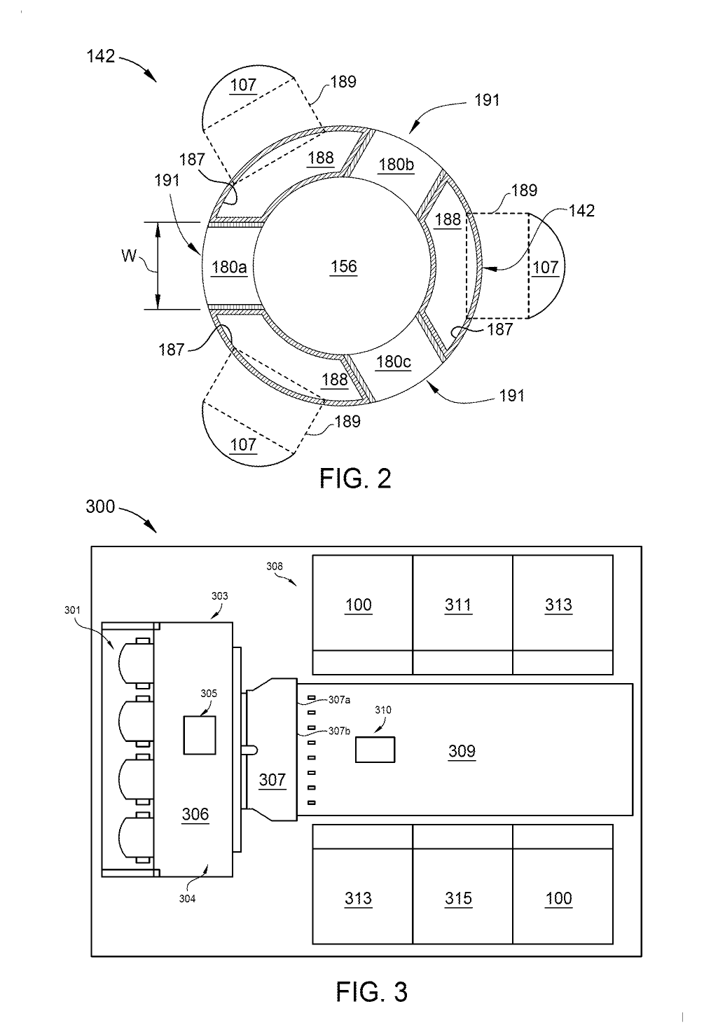

FIG. 3 is a schematic depiction of the layout of a substrate processing system 300 with the processing module 100 of FIG. 1A incorporated therein according to one or more embodiments.

The system 300 includes one or more front opening unified pods (FOUPs) 301 coupled to a factory interface 303. A robot 305 is disposed within the factory interface 303 and moves substrates from the FOUPs 301 to a stacked load lock chamber 307. The system 300 further includes a processing segment 308. The processing segment receives the substrates from the load lock chamber 307. A second robot 310 receives the substrates from the load lock chamber 307 and places the substrate into a stacked process module. The stacked process module may be the processing module 100.

The factory interface 303 includes a base surface 304. The robot 305 is disposed on the base surface 304 and within a transfer volume 306 of the factory interface 303. In some embodiments, the stacked load lock chamber 307 is a stacked load lock module.

The load lock chamber 307 includes a first load-lock chamber 307a, and a second load-lock chamber 307b. The second load-lock chamber 307b is disposed closer to the base surface 304 than the first load-lock chamber 307a.

In some embodiments, the load lock chamber 307 is coupled to the processing segment 308. The processing segment 308 includes a second robot 310 within a distribution region 309 of the processing segment 308. In some embodiments, the second robot 310 translates substrate between the module 100 as described in FIG. 1B, a metrology module 311, a deposition module 313, and an anneal module 315. The processing segment 308 may have any number of modules doing multiple operations simultaneously. In some embodiments, the modules 100, 311, 313, 315 are all stacked etching modules so that the system 300 can simultaneously process 12 substrates. As illustrated in FIG. 3, by having two modules 100, four substrates can simultaneously be etched using the symmetrical concept described in relation to chambers 101A and 101B.

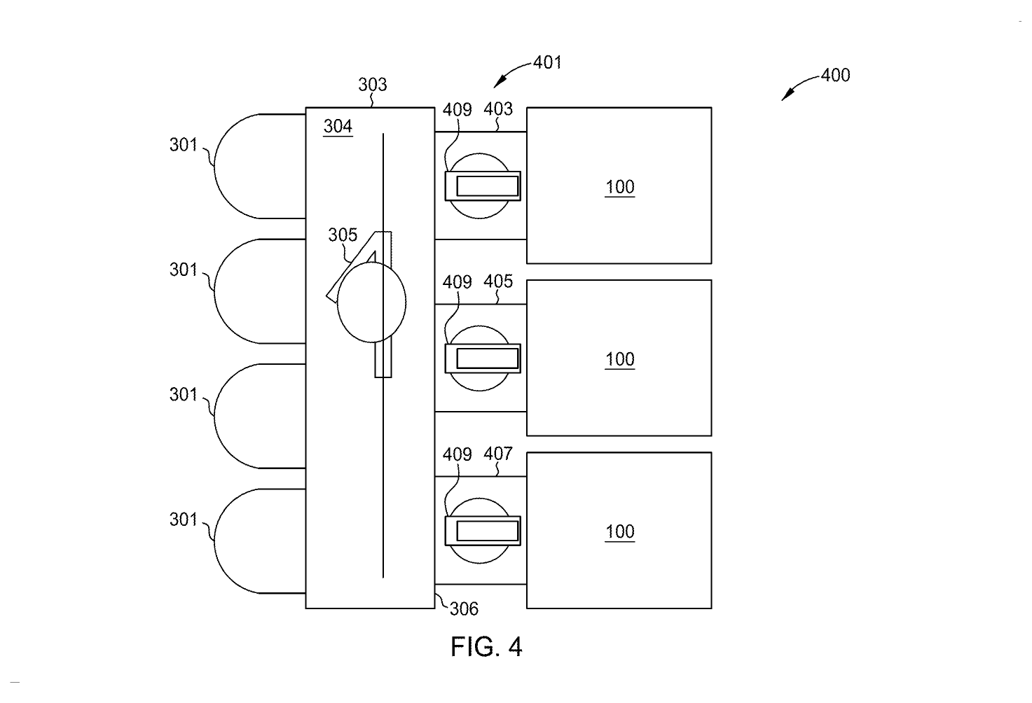

FIG. 4 is a schematic depiction of the layout of a substrate processing system 400 with the processing module 100 of FIG. 1A incorporated therein according to one or more embodiments.

The system 400 includes one or more front opening unified pods (FOUPs) 301 coupled to a factory interface 303. A robot 305 is disposed within the factory interface 303 and moves substrates from the FOUPs 301 to a plurality of stacked load lock chamber 401. The plurality of stacked load lock chamber 401 receives the substrates from factory interface 303.

The plurality of stacked load lock chamber 401 include a first load lock chamber 403, a second load lock chamber 405, and a third load lock chamber 407. Each load lock chamber of the plurality of stacked load lock chambers 401 includes a second robot 409 that receives the substrates from the factory interface 303 and places the substrate into a stacked process module. The stacked process module may be the processing module 100.

As illustrated in FIG. 4, by having three modules 100, six substrates can simultaneously be etched using the symmetrical concept described in relation to chambers 101A and 101B. This enables the system to better utilize floor space within a manufacturing facility

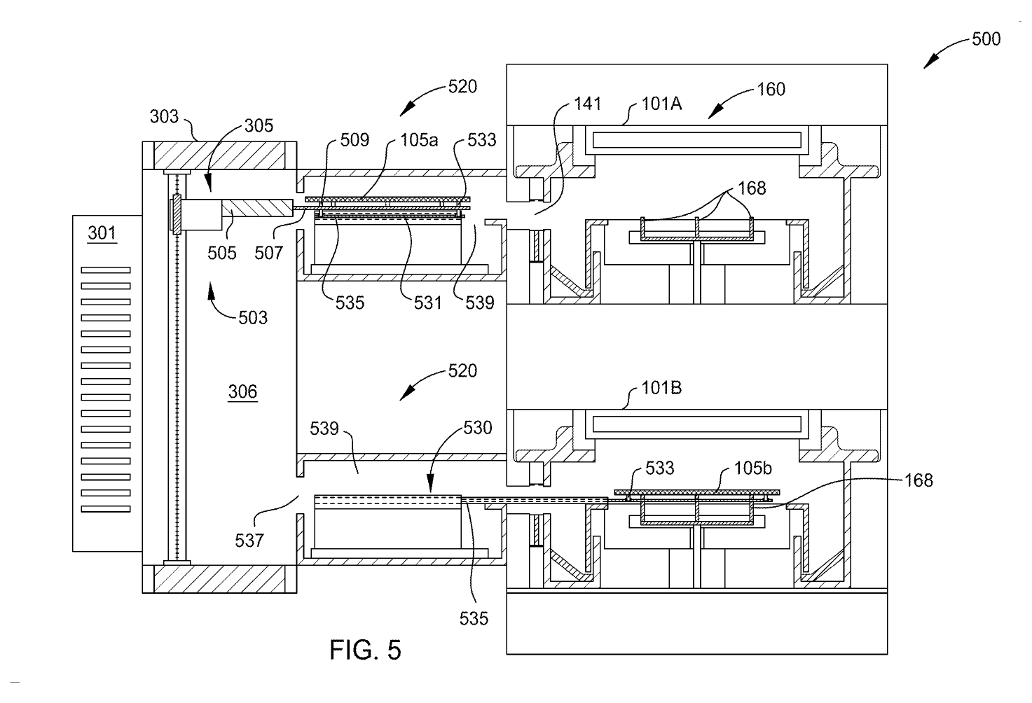

FIG. 5 is a schematic side view of a substrate processing system 500 with the processing module 100 of FIG. 1A incorporated therein according to one or more embodiments.

As shown, the processing system 500 includes the robot 305 disposed on the base surface 304 and within the transfer volume 306 of the factory interface 303. A FOUP 301 is coupled to the factory interface 303 and includes a plurality of vertically stacked substrates. The processing system 500 includes one or more load lock chambers 501. In some embodiments, the one or more load lock chambers 501 include a first load lock chamber 510 and a second load lock chamber 520. The load lock chambers 501 are disposed between the processing module 100 and the factory interface 303. In some embodiments, the first load lock chamber 510 is coupled to the first chamber 101A and the second load lock chamber 520 is coupled to the second chamber 101B of the processing module 100. The second load lock chamber 520 is disposed closer to the base surface 304 than the first load-lock chamber 510.

The robot 305 includes a movement mechanism 503 configured to translate an arm 505 within the transfer volume 306. The mechanism 503 is configured to enable the arm 505 to rotate, translate vertically, and translate horizontally within the transfer volume 306. The arm 505 includes a blade 507 with a plurality of pins 509 disposed thereon. The blade 507 is disposed on the distal end of the arm 505. The pins 509 are configured to support the substrate 105. The robot 305 picks a substrate from the FOUP 301 and translates the substrate through an aperture 537 and into one of the load lock chambers 501.

Each of the load lock chambers 501 includes a substrate shuttle 530. The substrate shuttle 530 is configured to translate the substrate 105 in and out of the processing module 100. For example, the substrate shuttle 530 of the first load lock chamber 510 receives a first substrate 105a from the plurality of pins 509 of the blade 507 while the substrate shuttle 530 of the second load lock chamber 520 is simultaneously translating a second substrate 105b over the lift pins 168 of the substrate support assembly 160 of the second chamber 101B.

In some embodiments, the substrate shuttle 530 includes a platform 531 with a plurality of platform pins 533 disposed thereon. The platform pins 533 are configured to support the substrate 105. The blade 507 of the robot 305 is configured to allow the exchange of the substrate 105 between the plurality of pins 509 of the blade 507 and the platform pins 533 of the platform 531. The platform 531 is configured to allow the exchange of the substrate 105 between the lift pins 168 and the platform pins 533. For example, the shape of the blade 507 and the location of the plurality of pins 509 form a “U” shape around the platform pins 533 so the robot 305 is able to vertically translate the blade 507 and transfer the substrate 105 between the plurality of pins 509 and the platform pins 533.

The platform 531 of the substrate shuttle 530 is disposed on an arm 535 that is configured to translate the platform 531. In some embodiments, the arm 535 includes an extension mechanism, for example a telescoping arm 535 that enables the platform 531 to translate from the first load lock chamber 510, through the slit valve tunnel 141, and over the substrate support assembly 160 in the first chamber 101A. When the substrate shuttle 530 disposes the substrate 105a over the substrate support assembly 160, the lift pins 168 are able to receive the substrate 105a from the platform pins 533 or lower a substrate onto the platform pins 533. In some embodiments, the substrate stays in the same horizontal plane while being transplanted by the substrate shuttle 530.

The load lock chambers 501 enable the processing module 100 to maintain a vacuum environment with a reduced volume while moving substrates between the transfer volume 306 and the first chamber 101A and the second chamber 101B. The load lock chambers 501 each include a chamber volume 539. The aperture 537 and the slit tunnel 141 are able to seal and form a sealed load lock chamber volume 539 within each of the first load lock chamber 510 and the second load lock chamber 520. When the aperture 537 and the slit tunnel 141 are not sealed the chamber volume 539 fluidly couples the transfer volume 306 of the factory interface 303 with the first chamber 101A and the second chamber 101B.

The incorporation of the load lock chambers 501 enables a reduction in foot print required by the processing system 500, thereby providing economic benefits and improving through-put.

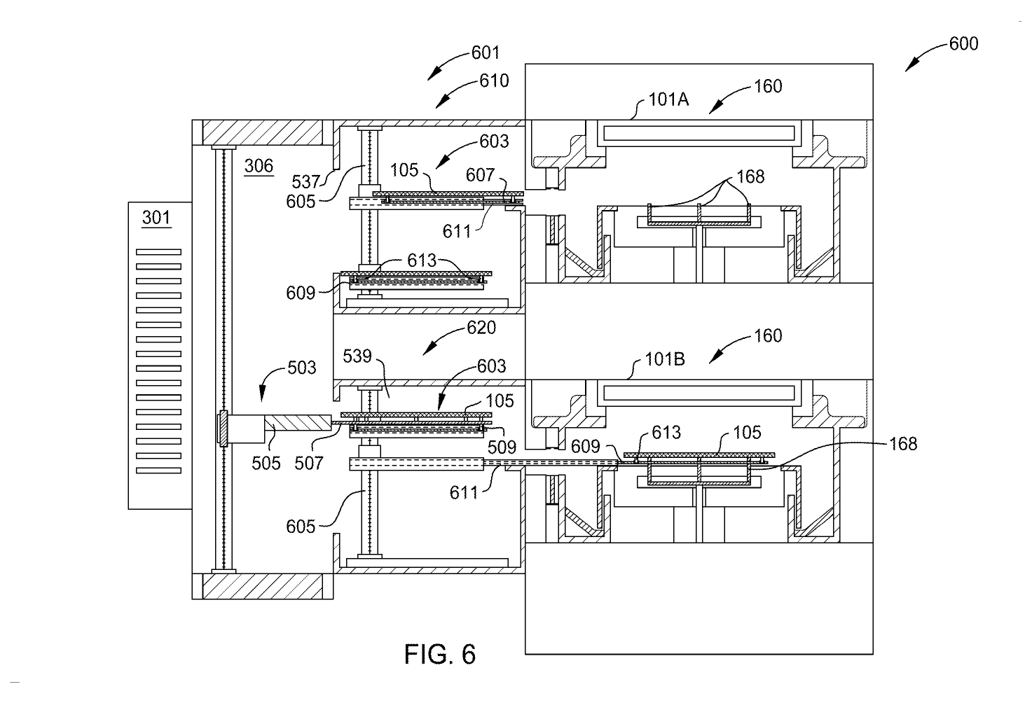

FIG. 6 is a schematic side view of a substrate processing system 600 with the processing module 100 of FIG. 1A incorporated therein according to one or more embodiments.

The substrate processing system 600 includes one or more load lock chambers 601. In some embodiments, the one or more load lock chambers 601 include a first load lock chamber 610 and a second load lock chamber 620. The load lock chambers 601 are disposed between the processing module 100 and the factory interface 303. In some embodiments, the first load lock chamber 610 is coupled to the first chamber 101A and the second load lock chamber 620 is coupled to the second chamber 101B of the processing module 100.

Each of the load lock chambers 601 includes a substrate shuttle 630. The substrate shuttle 630 is configured to translate substrates in and out of the processing module 100.

The substrate shuttle 630 of each load lock chamber 601 includes a lift system 605, a first arm 607, and a second arm 609. The lift system 605 raises and lowers the first arm 607 and the second arm 609. The arms 607, 609 each include an extension member 611 and a plurality of platform pins 613 disposed on the corresponding extension member 611. The plurality of platform pins 613 are configured to support the substrate 105. The blade 507 of the robot 305 is configured to allow the exchange of the substrate 105 between the plurality of pins 509 of the blade 507 and the platform pins 613 of the arms 607, 609. The arms 607, 609 are configured to allow the exchange of the substrate 105 between the lift pins 168 and the plurality of platform pins 613. In some embodiments, the arms 607, 609 and their corresponding extension members 611 form telescoping arms configured to translate substrate in and out of the corresponding the first chamber 101A and the second chamber 101B.

The lift system 605 aligns one of the arms 607, 609 with the slit valve tunnel 141 and the extension member 611 translates the corresponding platform through the slit valve tunnel 141 and over the substrate support assembly 160. When the substrate shuttle 630 disposes one of the first arm 607 or the second arm 609 over the substrate support assembly 160, the lift pins 168 are able to extend to receive the substrate 105 from the platform pins 613 or lower the substrate 105 onto the platform pins 613.

The lift system 605 enables each load lock chamber to unload a processed substrate from module 100 and load an unprocessed substrate into the module 100 simultaneously.

The load lock chambers 601 enables the processing module 100 to maintain a vacuum environment while moving substrates between load lock chamber volume 539 and the first chamber 101A and the second chamber 101B. For example, the load lock chambers 601 are sealed and pumped down to form a vacuum environment similar to the environment within the first chamber 101A and the second chamber 101B. The slit valve tunnels 141 are opened and the substrate shuttle 630 uses one of the first arm 607 or the second arm 609 to remove the processed substrate from the module 100. While still in a vacuum environment, the lift system 605 aligns the other of the first arm 607 or the second arm 609 to load an unprocessed substrate into the module 100. The above described operation can occur simultaneously using the first load lock chamber 610 and the second load lock chamber 620. While the module is processing the substrate, the robot 305 is able to translate processed substrates from the load lock chamber 601 and place them back into the FOUP 301.

Benefits of the present disclosure include enhanced etch uniformity of substrate surfaces, and increased throughput by the use of stacked symmetric chambers, reduced required system foot print, and enhanced use of vertical space. The stacked chambers within a single module enable a single exhaust assembly while maintaining the symmetric concept of the individual chambers. Utilizing a stacked approach for the etching chambers and/or the load lock chambers allows for a smaller footprint which results in additional cost savings.

While the foregoing is directed to embodiments of the present invention, other and further embodiments of the invention may be devised without departing from the basic scope thereof, and the scope thereof is determined by the claims that follow.

What is claimed is:

1. A module for semiconductor processing, comprising:
a first chamber comprising:
a first chamber body having a first central axis;
a first substrate support assembly that is disposed coincident with the first central axis; and
a plurality of first exhaust ports disposed through a first chamber body;
a second chamber comprising:
a second chamber body having a second central axis that is coincident with the first central axis;
a second substrate support assembly that is disposed coincident with the second central axis; and
a plurality of second exhaust ports disposed through the second chamber body; and
an exhaust assembly comprising:
a port coupled to a plenum, the plenum concentric with the first central axis and the second central axis; and
a plurality of exhaust conduits fluidly coupling the plurality of first exhaust ports, the plurality of second exhaust ports, and the plenum.

2. The module of claim 1, wherein the second chamber is disposed between the first chamber and the plenum.

3. The module of claim 1, wherein each exhaust conduit of the plurality of exhaust conduits corresponds to a first exhaust port of the plurality of first exhaust ports and a second exhaust port of the plurality of second exhaust ports.

4. The module of claim 1, wherein the plurality of first exhaust ports are distributed equally about the first central axis and each first exhaust port of the plurality of first exhaust ports is disposed perpendicular to the first central axis.

5. The module of claim 1, wherein each exhaust conduit of the plurality of exhaust conduits further comprises a restrictor disposed at each second exhaust port of the plurality of second exhaust ports.

6. The module of claim 1, wherein the first chamber further comprises a plurality of access tubes arranged in a spoke pattern symmetrical about the first central axis.

7. The module of claim 1, further comprising:
a support structure, the first chamber and the second chamber coupled to the support structure; and
a shield disposed between the first chamber body and a plasma source of the second chamber.

8. The module of claim 7, wherein the support structure is disposed between the first chamber, the second chamber, and the exhaust assembly.

9. A module for semiconductor processing, comprising:
a first etch chamber comprising:
a first chamber body having a first axis; and
a plurality of first exhaust ports fluidly coupled to the first chamber body;
a second etch chamber symmetric to the first etch chamber comprising:
a second chamber body having a second axis coincident with the first axis; and
a plurality of second exhaust ports fluidly coupled to the second chamber body and disposed symmetrically with the plurality of first exhaust ports; and
an exhaust assembly comprising:
a plenum coupled to the second etch chamber, disposed opposite the first etch chamber, and coincident with the first axis and the second axis; and
a plurality of exhaust conduits fluidly coupling the plurality of first exhaust ports, the plurality of second exhaust ports, and the plenum.

10. The module of claim 9, wherein the plurality of exhaust conduits are disposed symmetrically around the second axis and parallel to the first axis and the second axis.

11. The module of claim 9, wherein the first etch chamber and second etch chamber are stacked on the plenum of the exhaust assembly.

12. The module of claim 9, wherein the plurality of first exhaust ports comprise three first exhaust ports disposed about 120° from each other.

13. A system for semiconductor processing, comprising:
a factory interface comprising:
a base surface; and
a robot disposed on the base surface and within a transfer volume of the factory interface;
a stacked process module comprising:
a first chamber;
a second chamber coupled to the second chamber; and
an exhaust assembly coupled to the first chamber and the second chamber, the exhaust assembly comprising:
a plenum coupled to the second chamber and disposed opposite the first chamber; and
a plurality of exhaust conduits fluidly coupling the first chamber and the second chamber to the plenum;
a first load-lock chamber disposed between the a first chamber and the factory interface, the first load-lock chamber comprising:
a substrate shuttle configured to translate between the first load-lock chamber and the first chamber of the stacked process module; and
a second load-lock chamber disposed between the second chamber and the factory interface the second load-lock chamber.

14. The system of claim 13, wherein the plurality of exhaust conduits are symmetrically distributed and about parallel to a central axis of the stacked process module.

15. The system of claim 13, wherein the substrate shuttle comprises a telescoping arm.

16. The system of claim 13, wherein the plenum extends radially outward of the first chamber and the second chamber.

17. The system of claim 13, wherein the second chamber comprises a restrictor disposed in a second exhaust port of the second chamber, the restrictor configured to equalize pressure between a first exhaust port of the first chamber with the second exhaust port.

18. The system of claim 13, wherein the plenum comprises a pump port that is disposed coincident with a central axis of the stacked process module.

19. The system of claim 18, wherein the plenum further comprises a plurality of conduit ports disposed radially outward of the pump port, the plurality of conduit ports coupled to the plurality of exhaust conduits.

20. The system of claim 13, wherein the plurality of exhaust conduits further comprises 3 or more exhaust conduits.
